(19) United States
(12) Patent Application Publication
(10) Pub. No.: US 2025/0279761 A1
(43) Pub. Date: Sep. 4, 2025

(54) PIEZOELECTRIC VIBRATOR

(71) Applicant: Murata Manufacturing Co., Ltd., Nagaokakyo-shi (JP)

(72) Inventor: Taiki GOTO, Nagaokakyo-shi (JP)

(21) Appl. No.: 19/194,215

(22) Filed: Apr. 30, 2025

Related U.S. Application Data
(63) Continuation of application No. PCT/JP2023/024586, filed on Jul. 3, 2023.

(30) Foreign Application Priority Data
Dec. 26, 2022 (JP) 2022-209035

(51) Int. Cl. H03H 9/10; H03H 9/05; H03H 9/19

(52) U.S. Cl. CPC H03H 9/1021; H03H 9/0595; H03H 9/19

(57) ABSTRACT

A piezoelectric vibrator including: a vibrator layer having a vibrating portion, a holding portion surrounding a periphery of the vibrating portion, and a holding arm connecting the holding portion and the vibrating portion, the vibrating portion having a piezoelectric layer, a first electrode layer, and a second electrode layer; a first lid layer on a first electrode layer side of the vibrator layer; a second lid layer on a second electrode layer side of the vibrator layer; a first joining member joining the holding portion of the vibrator layer and the first lid layer; a second joining member joining the holding portion of the vibrator layer and the second lid layer; and a covering member covering an entire periphery of at least one of an inner surface and an outer surface of at least one of the first joining member and the second joining member.

### CROSS REFERENCE TO RELATED APPLICATIONS

The present application is a continuation of International application No. PCT/JP2023/024586, filed Jul. 3, 2023, which claims priority to Japanese Patent Application No. 2022-209035, filed Dec. 26, 2022, the entire contents of each of which are incorporated herein by reference.

### TECHNICAL FIELD

The present disclosure relates to a piezoelectric vibrator.

### BACKGROUND ART

In recent years, the miniaturization of vibrators has advanced. In general, a crystal vibrator with a wafer-level package structure obtained by bonding three wafers together is known, wherein the three wafers are a lid layer, a vibrator layer and a substrate layer. For example, Patent Document 1 discloses a crystal vibrator obtained by bonding three crystal wafers together using a low-melting glass or polyimide resin, which is an insulating material. Further, Patent Document 2 discloses a crystal vibrator obtained by joining three crystal wafers using Au, which is a conductor.
Patent Document 1: Japanese Unexamined Patent Application Publication No. 2013-38524
Patent Document 2: Japanese Unexamined Patent Application Publication No. 2022-99603

### SUMMARY OF THE DISCLOSURE

However, in the configuration of Patent Document 1, when the three crystal wafers are bonded together using a resin, since the resin generally has a high gas permeability, moisture and oxygen may enter the crystal vibrator from a resin sealing portion formed by the resin. Thus, moisture and oxygen entering the crystal vibrator react with the metal of the electrode film of a crystal vibrating element, causing the mass of the crystal vibrating element to fluctuate; and as a result, the long-term frequency stability of the crystal vibrating element may be impaired. Also, when each of the joining members of the three wafers is made of Au metal, as described in Patent Document 2, it is necessary to make the surface roughness of each surface of the wafers extremely small, so that it is difficult to reduce the cost.

The present disclosure has been made in view of the above problems, and an object of the present disclosure is to provide a piezoelectric vibrator with high reliability at low cost.

A piezoelectric vibrator according to an aspect of the present disclosure includes: a vibrator layer having a vibrating portion, a holding portion surrounding a periphery of the vibrating portion in a plan view of the piezoelectric vibrator, and a holding arm connecting the holding portion and the vibrating portion, the vibrating portion having a piezoelectric layer, first electrode layer on a first principal surface of the piezoelectric layer, and a second electrode layer on a second principal surface of the piezoelectric layer, the second principal surface facing the first principal surface; a first lid layer on a first electrode layer side of the vibrator layer; a second lid layer provided on a second electrode layer side of the vibrator layer; a first joining member surrounding the vibrating portion in the plan view and joining the holding portion of the vibrator layer and the first lid layer; a second joining member surrounding the vibrating portion in the plan view and joining the holding portion of the vibrator layer and the second lid layer; and a covering member covering an entire periphery of at least one of an inner surface and an outer surface of at least one of the first joining member and the second joining member, wherein the at least one of the first joining member and the second joining member is made of a first insulating material, and the covering member is made of a second insulating material having a gas permeability lower than that of the first insulating material.

In the present disclosure, the covering member made of the second insulating material having lower gas permeability than the first insulating material is used. By covering the entire periphery of at least one of the inner surface and the outer surface of at least one of the first joining member and the second joining member with the covering member, the gas-tight sealability of the interior can be enhanced, so that the frequency fluctuation of the piezoelectric vibrator can be suppressed. Further, since at least one of the first joining member and the second joining member is made of the first insulating material, the cost can be reduced compared with a configuration in which all joining members are made of metal. Therefore, it is possible to provide a piezoelectric vibrator with high reliability corresponding to reduced cost.

According to the present disclosure, it is possible to provide a piezoelectric vibrator with high reliability and at low cost.

### BRIEF DESCRIPTION OF THE DRAWINGS

FIG. 1 is an exploded perspective view schematically showing a piezoelectric vibrator according to a first embodiment.

FIG. 2 is a cross-sectional view of the piezoelectric vibrator according to the first embodiment taken along line II-II of FIG. 1.

FIG. 3 is a cross-sectional view showing a configuration of a piezoelectric vibrator according to a second embodiment.

FIG. 4 is a cross-sectional view showing a configuration of a piezoelectric vibrator according to a third embodiment.

FIG. 5 is a plan view showing a configuration of a crystal vibrating element according to a fourth embodiment.

### DESCRIPTION OF THE PREFERRED EMBODIMENTS

Embodiments of the present disclosure will be described below with reference to the drawings. Note that the drawings of the present embodiment are exemplary, the dimensions and shapes of each component are schematic, and the technical scope of the present disclosure should not be construed as limiting to the present embodiment.

For convenience, each drawing may be accompanied by a Cartesian coordinate system consisting of X axis, Y′ axis and Z′ axis to clarify the relationship between each drawing and to help understand the positional relationship of each component. The X axis, Y′ axis and Z′ axis correspond to each other in each drawing. The X axis, Y′ axis and Z′ axis correspond to the crystallographic axes of a quartz crystal blank, which is to be described later, respectively. The X axis corresponds to the electrical axis (polarity axis) of the quartz crystal, the Y axis corresponds to the mechanical axis of the quartz crystal, and the Z axis corresponds to the optical axis of the quartz crystal. The Y′ axis and the Z′ axis are axes obtained by rotating the Y axis and the Z axis by 35 degrees 15 minutes±1 minute 30 seconds from the Y axis to the Z axis around the X axis, respectively.

### First Embodiment

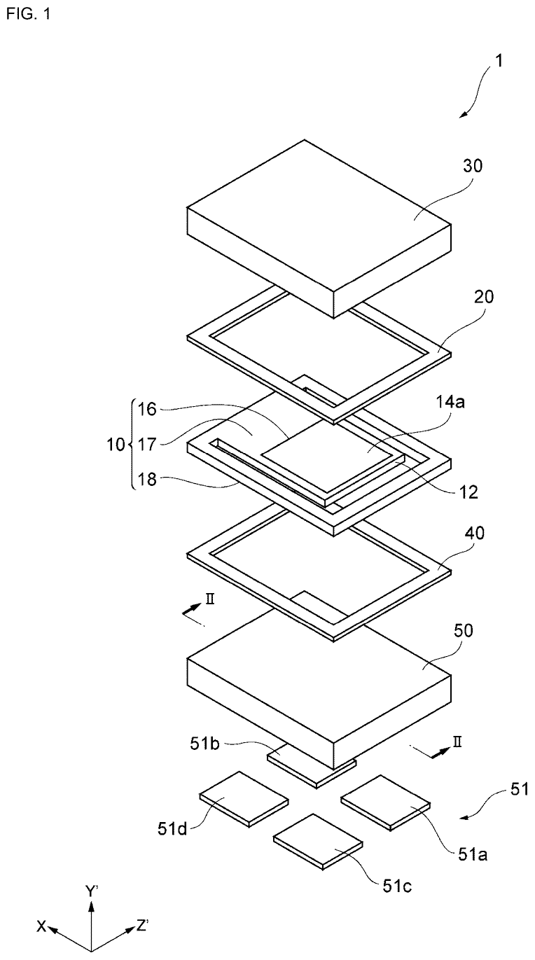

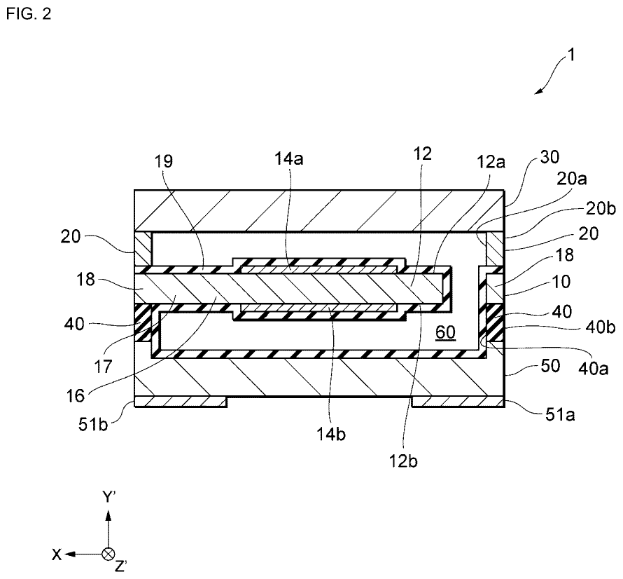

A configuration of a piezoelectric vibrator 1 according to a first embodiment of the present disclosure will be described with reference to FIGS. 1 and 2. FIG. 1 is an exploded perspective view schematically showing the piezoelectric vibrator 1 according to the present embodiment. FIG. 2 is a cross-sectional view of the piezoelectric vibrator 1 according to the present embodiment taken along line II-II of FIG. 1.

The piezoelectric vibrator 1 according to the present embodiment includes a crystal vibrating element 10, a first joining member 20, an upper lid layer 30, a second joining member 40, and a lower lid layer 50. In the following description, the crystal vibrating element 10 having a quartz crystal blank 12 will be described as an example of a piezoelectric vibrating element of the piezoelectric vibrator 1. The quartz crystal blank 12 is a kind of piezoelectric body (piezoelectric piece) that vibrates in response to a voltage applied thereto. Note that the piezoelectric vibrating element is not limited to the crystal vibrating element 10, but other piezoelectric bodies such as ceramic or the like may be used as the piezoelectric vibrating element. Further, the piezoelectric vibrating element may alternatively be a MEMS vibrating element manufactured using MEMS technology.

The crystal vibrating element 10 (corresponding to an example of a “vibrator layer”) is an element that vibrates a quartz crystal by a piezoelectric effect to convert electric energy and mechanical energy. The crystal vibrating element 10 includes an AT-cut type quartz crystal blank 12. When axes obtained by rotating, among an X axis, a Y axis, and a Z axis as crystallographic axes of synthetic quartz crystal, the Y axis and the Z axis about the X axis by 35 degrees 15 minutes±1 minute 30 seconds in the direction from the Y axis to the Z axis are defined as a Y′ axis and a Z′ axis, respectively, the AT-cut type quartz crystal blank 12 is cut out such that its principal surface lies in an XZ′ plane specified by the X axis and the Z′ axis. The quartz crystal blank 12 may be a tuning fork type quartz crystal blank.

Note that the rotation angle of the Y′ axis and the Z′ axis of the AT-cut type quartz crystal blank 12 may be tilted from 35 degrees 15 minutes by an amount within a range of −5 degrees to +15 degrees. Alternatively, cuts other than AT cut, such as BT cut, GT cut, SC cut, and the like may be used as the cut angle of the quartz crystal blank 12.

A crystal vibrating element using the AT-cut type quartz crystal blank has high frequency stability over a wide temperature range. Further, an AT-cut crystal vibrating element has excellent aging characteristics and can be manufactured at low cost. Further, the AT-cut crystal vibrating element uses a thickness shear vibration mode as the main vibration.

The crystal vibrating element 10 includes a set of excitation electrodes. An alternating electric field is applied between the set of excitation electrodes. With such a configuration, the vibrating portion of the quartz crystal blank 12 vibrates at a predetermined oscillation frequency by the thickness shear vibration mode, so that resonance characteristics associated with the vibration are obtained.

Thus, since the main vibration of the crystal vibrating element 10 is the thickness shear vibration mode, a crystal vibrating element that performs thickness shear vibration at a vibration frequency in an MHz band can be easily realized by using, for example, the AT-cut type quartz crystal blank 12.

The quartz crystal blank 12 (corresponding to an example of a “piezoelectric layer”) has a first principal surface 12a and a second principal surface 12b lying in the XZ′ plane and facing each other. The quartz crystal blank 12 has a flat plate shape. Therefore, the first principal surface 12a and the second principal surface 12b of the quartz crystal blank 12 are flat surfaces, respectively. Note that the quartz crystal blank 12 is not limited to a flat plate shape, but may have a convex or concave central portion, for example.

The AT-cut type quartz crystal blank 12 has a long side direction in which a long side parallel to the X axis direction extends, a short side direction in which a short side parallel to the Z′ axis direction extends, and a thickness direction in which a thickness parallel to the Y′ axis direction extends. The quartz crystal blank 12 has a rectangular shape when the first principal surface 12a of the quartz crystal blank 12 is viewed in plan view (hereinafter simply referred to as “in plan view”). The quartz crystal blank 12 may be thinned to a predetermined thickness by, for example, polishing after being joined to the second joining member 40 in a state having a larger thickness.

The planar shape of the quartz crystal blank 12 is not limited to a rectangular shape. The planar shape of the quartz crystal blank 12 may alternatively be a polygonal shape, a circular shape, an elliptical shape, or a combination of these shapes.

The crystal vibrating element 10 includes a vibrating portion 16, a holding arm 17, and a holding portion 18. The vibrating portion 16 has the quartz crystal blank 12 and the set of excitation electrodes. The set of excitation electrodes includes a first excitation electrode 14a (corresponding to an example of an “upper electrode layer”) and a second excitation electrode 14b (corresponding to an example of a “lower electrode layer”). The first excitation electrode 14a is provided on the first principal surface 12a of the vibrating portion 16, and the second excitation electrode 14b is provided on the second principal surface 12b of the vibrating portion 16. The first excitation electrode 14a and the second excitation electrode 14b are provided facing each other with the quartz crystal blank 12 sandwiched therebetween. The first excitation electrode 14a and the second excitation electrode 14b each have a rectangular shape when the first principal surface 12a is viewed in plan view, and are arranged so that substantially the whole of the first excitation electrode 14a and substantially the whole of the second excitation electrode 14b overlap each other in the XZ′ plane.

The shape of each of the first excitation electrode 14a and the second excitation electrode 14b is not limited to a rectangular shape, but may be a polygonal shape, a circular shape, an elliptical shape, or a combination of these shapes.

The crystal vibrating element 10 has extended electrodes and connecting electrodes (both not shown), and the first excitation electrode 14a is electrically connected to an outer electrode 51a, and the second excitation electrode 14b is electrically connected to an outer electrode 51d, for example, by these electrodes. By applying an alternating electric field to the first excitation electrode 14a and the second excitation electrode 14b via the outer electrodes 51a and 51d, the vibrating portion 16 (specifically, a portion of the quartz crystal blank 12 where the first excitation electrode 14a and the second excitation electrode 14b are provided) vibrates in a predetermined vibration mode.

The materials of the first excitation electrode 14a, the second excitation electrode 14b, the extended electrodes, and the connecting electrodes are, for example, aluminum (Al), molybdenum (Mo), or gold (Au). Each of the electrodes described above may be, for example, a multilayer body composed of a titanium (Ti) layer provided on the quartz crystal blank 12 side and a gold (Au) layer provided on the surface side.

The crystal vibrating element 10 is accommodated in an inner space 60 formed between the first joining member 20, the upper lid layer 30, the second joining member 40, and the lower lid layer 50. The inner space 60 is gas-tightly sealed, for example. Note that the inner space 60 may be gas-tightly sealed in a vacuum state or gas-tightly sealed in a state filled with a gas such as an inert gas.

The vibrating portion 16 is a portion of the crystal vibrating element 10 and is located in a central portion of the inner space 60. As shown in FIG. 2, the vibrating portion 16 has the first principal surface 12a and the second principal surface 12b facing the first principal surface 12a. The vibrating portion 16 has the first excitation electrode 14a provided on the first principal surface 12a and the second excitation electrode 14b provided on the second principal surface 12b. The first excitation electrode 14a is provided on a surface of the quartz crystal blank 12 facing the upper lid layer 30, and the second excitation electrode 14b is provided on a surface of the quartz crystal blank 12 facing the lower lid layer 50.

Similar to the vibrating portion 16, the holding arm 17 is also located in the inner space 60, and connects the vibrating portion 16 and the holding portion 18. The extended electrodes (not shown) are formed on the holding arm 17, and can lead the first excitation electrode 14a and the second excitation electrode 14b to the connecting electrodes provided on the holding portion 18.

The holding portion 18 is formed in a frame shape that surrounds the periphery of the vibrating portion 16 in plan view. The holding portion 18 is joined to the first joining member 20 and the second joining member 40 in the vertical direction. The holding portion 18 is connected to the holding arm 17.

A covering member 19 is made of an insulating material having lower gas permeability than an insulating material of the second joining member 40, which will be described later. For example, aluminum oxide (Al2O3) is used as the insulating material of the covering member 19. In the example shown in FIG. 2, the covering member 19 is provided to cover an inner surface 40a of the second joining member 40. Specifically, the covering member 19 is provided on the surface of the crystal vibrating element 10, the inner surface 40a of the second joining member 40, and a upper surface of the lower lid layer 50 facing the vibrating portion. For example, in a case where a first wafer constituting a plurality of lower lid layers 50, a second wafer constituting a plurality of crystal vibrating elements 10, and a wafer constituting a plurality of upper lid layers 30 are bonded to each other, and then each wafer is cut with a dicing machine to obtain a plurality of piezoelectric vibrators 1, the covering member 19 can be formed after the first wafer and the second wafer are bonded to each other. The thickness of the covering member 19 is 1 nm to 100 nm, and preferably 5 nm to 50 nm. ALD (atomic layer deposition), CVD (chemical vapor deposition), PVD (physical vapor deposition), or the like can be used as the film formation method of the covering member 19. A Film with low gas permeability can be easily formed by the ALD, CVD, or PVD described above. In particular, when the ALD is used, the covering member 19 with low gas permeability can be formed even in a thick structure with uneven surfaces and undulations. The covering member 19 is not limited to being provided in the locations described above, but may be provided, for example, only on the inner surface 40a of the second joining member 40, as in the second embodiment to be described later, or on an outer surface 20b of the first joining member 20 and an outer surface 40b of the second joining member 40, as in a third embodiment to be described later.

In the present embodiment, the first joining member 20 is made of a metallic material. The first joining member 20 is provided between a upper surface side of the holding portion 18 and the upper lid layer 30 to metal-join the holding portion 18 and the upper lid layer 30. The first joining member 20 is provided so as to surround the vibrating portion 16 in plan view, and joins the holding portion 18 of the crystal vibrating element 10 and the upper lid layer 30 in a frame shape. The first joining member 20 has the inner surface 20a and the outer surface 20b, wherein the inner surface 20a is in contact with the inner space 60, and the outer surface 20b is on the opposite side of the inner surface 20a with the first joining member 20 sandwiched therebetween. Au—Au joining, AuSn joining, AlGe joining, or the like may be used as the metal joining as long as airtightness can be obtained in the inner space 60.

The upper lid layer 30 is formed in a flat plate shape, for example. The dimensions of the upper lid layer 30 in plan view are the same or substantially the same as the dimensions of the crystal vibrating element 10. The upper lid layer 30 is provided on the first excitation electrode 14a side of the crystal vibrating element 10. The upper lid layer 30 is joined to the first joining member 20 to thereby form a portion of the inner space 60 by. The upper lid layer 30 may be made of quartz crystal, or, alternatively, may be made of silicon, ceramic, or glass.

In the present embodiment, the second joining member 40 is made of an insulating material. For example, a resin or a glass may be used as the insulating material of the second joining member 40. For example, polyimide resin may be used as the resin. Also, a low-melting glass may be used as the glass. The second joining member 40 is provided between the lower surface side of the holding portion 18 and the lower lid layer 50 to join the holding portion 18 and the lower lid layer 50. The second joining member 40 is provided so as to surround the vibrating portion 16 in plan view, and joins the holding portion 18 of the crystal vibrating element 10 and the lower lid layer 50 in a frame shape. The second joining member 40 has the inner surface 40a and the outer surface 40b, wherein the inner surface 40a faces the inner space 60, and the outer surface 40b is on the opposite side of the inner surface 40a with the second joining member 40 sandwiched therebetween. In the present embodiment, the covering member 19 is provided on the inner surface 40a. With such a configuration, the gas permeating through the second joining member 40 is blocked by the covering member 19, so that the gas-tight sealability of the inner space 60 can be improved. Further, by forming the second joining member 40 on the side of the lower lid layer 50 where outer electrodes 51, which will be described later, are provided, with an insulating material, it is possible to achieve miniaturization and good electrical characteristics compared to, for example, the configuration disclosed in Patent Document 2, in which a metal joining is used. That is, in the configuration disclosed in Patent Document 2 in which the metal joining is used, since wiring lines cannot be drawn across the joining member made of metal, it is necessary to form via(s) in the vibrating element, so that it is difficult to secure a sufficient area of the vibrating portion. On the other hand, in the configuration of the present embodiment, since the crystal vibrating element 10 and the lower lid layer 50 are joined by the second joining member 40 made of an insulating material, the wiring lines can be drawn across the second joining member 40, so that it is not necessary to form the via(s) in the crystal vibrating element 10. Therefore, it is possible to maximize the first excitation electrode 14a and the second excitation electrode 14b of the vibrating portion 16 to obtain good electrical characteristics equivalent to those of a large-sized product and to achieve miniaturization of the piezoelectric vibrator 1.

The lower lid layer 50 is formed in a flat plate shape, for example. The dimensions of the lower lid layer 50 in plan view are the same or substantially the same as the dimensions of the crystal vibrating element 10. The lower lid layer 50 is provided on the second excitation electrode 14b side of the crystal vibrating element 10. The lower lid layer 50 is joined to the second joining member 40 to thereby form a portion of the inner space 60. The lower lid layer 50 may be made of quartz crystal, or, alternatively, may be made of silicon, ceramic, or glass. By forming at least one of the upper lid layer 30 and the lower lid layer 50 with silicon, glass, or ceramic having low transparency to visible light, image recognition, mounting positioning and the like can be easily performed when mounting the piezoelectric vibrator 1. The lower lid layer 50 has the outer electrodes 51 on the side opposite to the side facing the crystal vibrating element 10.

Outer electrodes 51a, 51b, 51c, and 51d are provided at four corners of the lower lid layer 50. The outer electrode 51a is electrically connected to the first excitation electrode 14a, and the outer electrode 51d is electrically connected to the second excitation electrode 14b. The outer electrodes 51b and 51c may be used as dummy electrodes that are not electrically connected to the crystal vibrating element 10. With such an electrode arrangement, when mounting the piezoelectric vibrator 1 on a substrate, even if the piezoelectric vibrator 1 is mounted upside down, the piezoelectric vibrator 1 can be mounted because the positions of the outer electrodes are symmetrical. Further, by securing the maximum distance between the outer electrode 51a and the outer electrode 51d, a short circuit between the two electrodes can be suppressed.

The inner space 60 is formed inside the piezoelectric vibrator 1 by the first joining member 20, the upper lid layer 30, the second joining member 40, and the lower lid layer 50. The vibrating portion 16 and the holding arm 17 are provided in the inner space 60 to constitute a vibration space of the crystal vibrating element 10.

As described above, in the piezoelectric vibrator 1 according to the present embodiment, the inner surface 40a of the second joining member 40 is covered by the covering member 19. With such a configuration, the gas entering from the outside of the piezoelectric vibrator 1 through the second joining member 40 is blocked by the covering member 19 made of an insulating material having a gas permeability lower than that of the insulating material of the second joining member 40, so that the gas-tight sealability of the inner space 60 can be enhanced. Further, by forming the second joining member 40 with an insulating material, the cost can be reduced as compared with a configuration in which all joining members are made of metal.

In the present embodiment, the covering member 19 is provided on the inner surface 40a of the second joining member 40; however, the covering member 19 is not limited to being provided on the inner surface 40a of the second joining member 40, but may be provided to cover the entire periphery of at least one of the inner surfaces 20a and 40a and the outer surfaces 20b and 40b of at least one of the first joining member 20 and the second joining member 40. For example, the covering member 19 may be provided on the outer surface 40b of the second joining member 40 or on both the inner surface 40a and the outer surface 40b of the second joining member 40. The present embodiment describes an aspect in which the crystal vibrating element 10 and the upper lid layer 30 are metal-joined by the first joining member 20; however, when the first joining member 20 is made of an insulating material, at least one of the inner surface 20a and the outer surface 20b of the first joining member 20 may be covered by the covering member 19, similar to the case of the second joining member 40.

Further, the present embodiment describes a configuration in which the first joining member 20 is made of a metallic material, the second joining member 40 is made of an insulating material, and the second joining member 40 is covered by the covering member 19; however, the present disclosure is not limited to such a configuration as long as at least one of the joining members is made of an insulating material. For example, when the first joining member 20 is made of an insulating material, the first joining member 20 may be covered by the covering member 19.

Further, in the present embodiment, the covering member 19 is provided on surfaces of each of the first excitation electrode 14a and the second excitation electrode 14b of the crystal vibrating element 10. With such a configuration, by covering the surfaces of the first excitation electrode 14a and the second excitation electrode 14b with the covering member 19, oxidation of the first excitation electrode 14a and the second excitation electrode 14b can be suppressed.

A configuration of a resin sealing device and a resin sealing method according to another embodiment of the present disclosure will be described below. In the following embodiments, descriptions of the matters common to those of the first embodiment will be omitted and only the differences will be described. In particular, similar effects due to similar configurations will not be described one by one.

### Second Embodiment

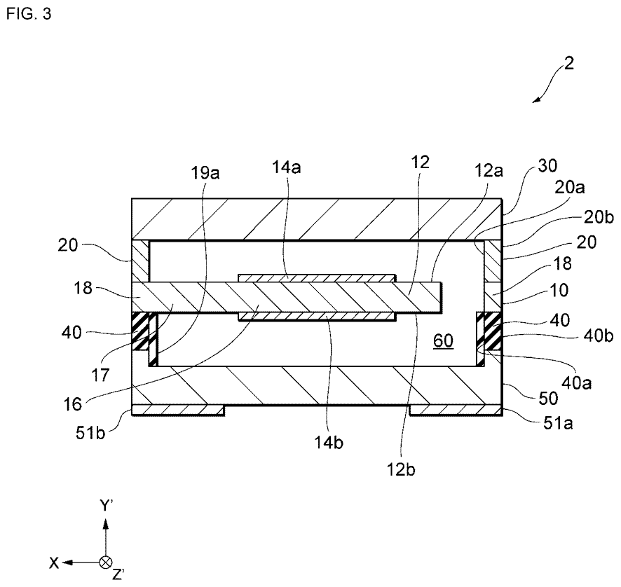

Next, the structure of a piezoelectric vibrator 2 according to a second embodiment will be described with reference to FIG. 3. FIG. 3 is a cross-sectional view schematically showing the structure of the piezoelectric vibrator according to the second embodiment.

The present embodiment differs from the first embodiment in the positions where the covering member 19 is provided. Specifically, in the first embodiment, the covering member 19 is provided on the surface of the crystal vibrating element 10, the inner surface 40a of the second joining member 40, and the upper surface of the lower lid layer 50 facing the vibrating portion; while in the present embodiment, a covering member 19a is partially provided on the inner surface 40a of the second joining member 40. In such a case, the covering member 19a is provided to avoid a surface of the crystal vibrating element 10 joined to the first joining member 20. With such a configuration, the joinability between the crystal vibrating element 10 and the upper lid layer 30 can be improved. Further, the covering member 19a is provided to avoid each surface of the first excitation electrode 14a and the second excitation electrode 14b of the vibrating portion 16. With such a configuration, when the covering member 19a has the gas adsorption property, the vibration characteristic fluctuation of the vibrating portion 16 due to the weight fluctuation of the covering member can be suppressed.

### Third Embodiment

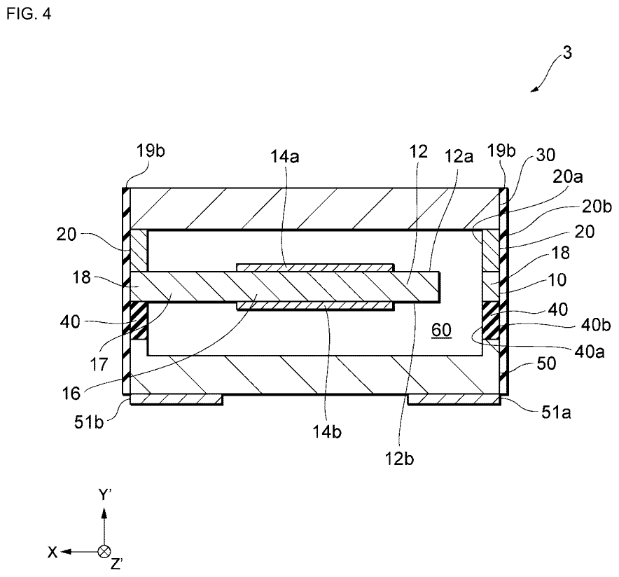

Next, the structure of a piezoelectric vibrator 3 according to a third embodiment will be described with reference to FIG. 4. FIG. 4 is a cross-sectional view schematically showing the structure of the piezoelectric vibrator according to the third embodiment.

The present embodiment differs from the first embodiment in the positions where the covering member 19 is provided. Specifically, in the first embodiment, the covering member 19 is provided on the surface of the crystal vibrating element 10, the inner surface 40a of the second joining member 40, and the upper surface of the lower lid layer 50 facing the vibrating portion; while in the present embodiment, a covering member 19b is provided on the entire side surface of the piezoelectric vibrator 3 so as to cover the outer surface 20b of the first joining member 20 and the outer surface 40b of the second joining member 40. With such a configuration, since not only the second joining member 40 but also the first joining member 20 can be covered, the first joining member can be formed an insulating material, so that the cost can be further reduced.

### Fourth Embodiment

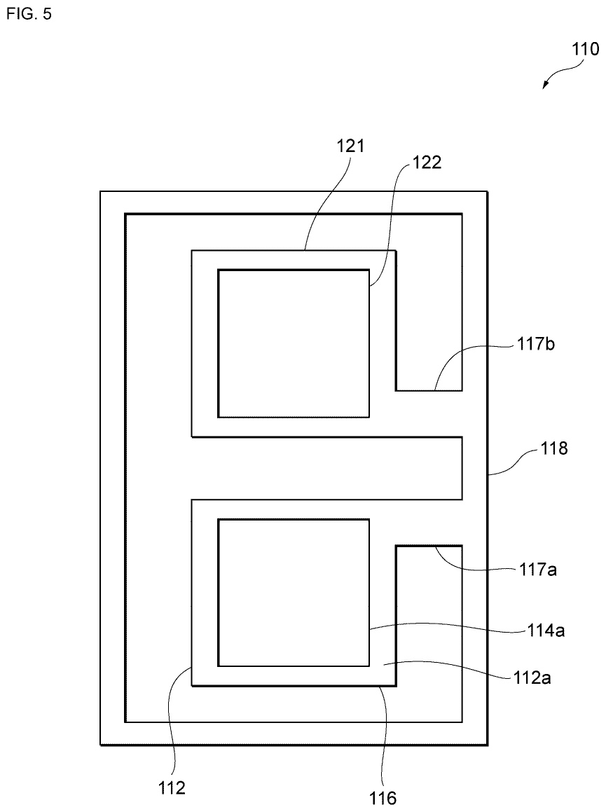

Next, the structure of a crystal vibrating element 110 according to a fourth embodiment will be described with reference to FIG. 5. FIG. 5 is a plan view schematically showing the structure of the crystal vibrating element according to the fourth embodiment.

In the present embodiment, unlike the first embodiment, the crystal vibrating element 110 further includes functional element(s) that assist the function of the piezoelectric vibrator. For example, as shown in FIG. 5, a temperature sensor mounting portion 121 and a temperature sensor 122 are provided in the inner space 60. The crystal vibrating element 110 has a holding arm 117a that connects a vibrating portion 116 and a holding portion 118, and a holding arm 117b that connects the holding portion 118 and the temperature sensor mounting portion 121. The temperature sensor 122 is provided on the temperature sensor mounting portion 121. For example, a thermistor that detects a change in temperature as a change in resistance value is used as the temperature sensor 122. By providing the thermistor, frequency temperature correction can be improved as compared with a conventional crystal vibrator. When a thermistor is used, the temperature change can be detected more accurately by disposing the thermistor near a quartz crystal blank 112 and a first excitation electrode 114a of the vibrating portion 116 as shown in FIG. 5. Further, the temperature of the quartz crystal blank 112 can be detected more accurately by performing adjustment so that the heat flow rate from the substrate on which the crystal vibrator is equal between the vibrating portion 116 and the temperature sensor mounting portion 121, and performing adjustment so that the heat capacity of the quartz crystal blank 112 and the heat capacity of the temperature sensor 122 are equal.

An inductor may be used as an example of the functional element(s). The inductor is composed as a portion of an LC circuit and has a function as a high pass filter that cuts frequencies lower than a predetermined frequency. By providing the inductor on the crystal vibrating element 110, it is possible to provide a crystal vibrating element with an inductor that can be manufactured at a lower cost than a configuration in which a filter using an inductor is formed on an external circuit. Further, by providing the functional element(s) in the inner space 60 with a high gas-tight sealability, deterioration of the functional element(s) over time can be suppressed. Further, by providing the functional element(s) in the inner space 60, it is possible to reduce the number of protective components of the functional element(s).

A part or all of the embodiments of the present disclosure will be described below. The present disclosure is not limited to the following description.

<1> A piezoelectric vibrator according to an aspect of the present disclosure comprising: a vibrator layer having a vibrating portion, a holding portion surrounding a periphery of the vibrating portion in plan view, and a holding arm connecting the holding portion and the vibrating portion, the vibrating portion having a piezoelectric layer, an upper electrode layer provided on a first principal surface of the piezoelectric layer, and a lower electrode layer provided on a second principal surface of the piezoelectric layer, the second principal surface facing the first principal surface; an upper lid layer provided on an upper electrode layer side of the vibrator layer; a lower lid layer provided on a lower electrode layer side of the vibrator layer; a first joining member provided so as to surround the vibrating portion in plan view and joining the holding portion of the vibrator layer and the upper lid layer; a second joining member provided so as to surround the vibrating portion in plan view and joining the holding portion of the vibrator layer and the lower lid layer; and a covering member provided so as to cover an entire periphery of at least one of an inner surface and an outer surface of at least one of the first joining member and the second joining member, wherein the at least one of the first joining member and the second joining member is made of a first insulating material, and the covering member is made of a second insulating material having a gas permeability lower than that of the first insulating material.

According to the above aspect, by covering the inner surface and outer surface of at least one of the first joining member and the second joining member with a covering member having low gas permeability, gas entering from the first joining member or the second joining member can be suppressed, and long-term frequency stability can be improved. Further, by forming at least one of the first joining member and the second joining member with the first insulating material, it is possible to reduce the cost as compared with a configuration in which all joining members are made of metal.

<2> As an aspect, the piezoelectric vibrator according to <1>, wherein the lower lid layer has an outer electrode on a side opposite to a side facing the vibrator layer, the first joining member is made of a metallic material, and the second joining member is made of the first insulating material.

According to the above aspect, compared with a configuration in which the second joining member and the lower lid layer are joined by metal, it is not necessary to provide via(s) in the lower lid layer, so that the upper electrode layer and the lower electrode layer can be maximized, which corresponds to miniaturization.

<3> As an aspect, the piezoelectric vibrator according to <2>, wherein the vibrator layer further has a functional element.

<4> As an aspect, the piezoelectric vibrator according to <1>, wherein the covering member is provided to avoid each surface of the upper electrode layer and the lower electrode layer of the vibrating portion.

According to the above aspect, it is possible to prevent the frequency characteristics of the vibrating portion from fluctuating due to the gas adsorption property of the covering member.

<5> As an aspect, the piezoelectric vibrator according to any one of <1> to <3>, wherein the covering member is further provided on each surface of the upper electrode layer and the lower electrode layer of the vibrating portion.

According to the above aspect, by covering the upper electrode and the lower electrode with the covering member, the frequency fluctuation due to the oxidation of the electrodes can be suppressed.

<6> As an aspect, the piezoelectric vibrator according to any one of <1> to <3>, wherein the covering member is provided to avoid a surface of the vibrator layer joined to the first joining member.

According to the above aspect, the joinability between the vibrator layer and the first joining member can be improved.

<7> As an aspect, the piezoelectric vibrator according to any one of <1> to <6>, wherein the piezoelectric layer of the vibrator layer is made of quartz crystal.

<8> As an aspect, the piezoelectric vibrator according to any one of <1> to <7>, wherein the upper lid layer and the lower lid layer are made of quartz crystal.

<9> As an aspect, the piezoelectric vibrator according to any one of <1> to <7>, wherein at least one of the upper lid layer and the lower lid layer is made of silicon, ceramic, or glass.

According to the above aspect, image recognition can be easily performed when mounting the piezoelectric vibrator to a substrate.

<10> As an aspect, the piezoelectric vibrator according to any one of <1> to <9>, wherein the covering member has a thickness of 1 nm to 100 nm.

<11> As an aspect, the piezoelectric vibrator according to any one of <1> to <10>, wherein the first insulating material is made of resin or glass, and the second insulating material is made of aluminum oxide.

It should be noted that the embodiments described above are intended to facilitate understanding of the present disclosure, and are not intended to limit the interpretation of the present disclosure. The present disclosure may be changed/improved without departing from its scope, and the present disclosure also includes equivalents thereof. In other words, appropriate design changes made to each embodiment by those skilled in the art are included in the scope of the disclosure as long as the features of the present disclosure are provided. For example, the respective elements included in each embodiment, and the arrangements, materials, conditions, shapes, sizes, and the like of the elements are not limited to those exemplified but can be changed appropriately. Further, the respective elements included in each embodiment may be combined as long as it is technically possible, and the combinations of the elements are within the scope of the present disclosure as long as they have the features of the present disclosure.

### REFERENCE SIGNS LIST

1, 2, 3 piezoelectric vibrator
10, 110 crystal vibrating element
12, 112 quartz crystal blank
12a, 112a first principal surface
12b second principal surface
14a, 114a first excitation electrode
14b second excitation electrode
16, 116 vibrating portion
17, 117a, 117b holding arm
18, 118 holding portion
19, 19a, 19b covering member
20 first joining member
20a inner surface
20b outer surface
30 upper lid layer
40 second joining member
40a inner surface
40b outer surface
50 lower lid layer
51, 51a, 51b, 51c, 51d outer electrode
60 inner space
121 temperature sensor mounting portion
122 temperature sensor

1. A piezoelectric vibrator comprising:
a vibrator layer having a vibrating portion, a holding portion surrounding a periphery of the vibrating portion in a plan view of the piezoelectric vibrator, and a holding arm connecting the holding portion and the vibrating portion, the vibrating portion having a piezoelectric layer, first electrode layer on a first principal surface of the piezoelectric layer, and a second electrode layer on a second principal surface of the piezoelectric layer, the second principal surface facing the first principal surface;
a first lid layer on a first electrode layer side of the vibrator layer;
a second lid layer provided on a second electrode layer side of the vibrator layer;
a first joining member surrounding the vibrating portion in the plan view and joining the holding portion of the vibrator layer and the first lid layer;
a second joining member surrounding the vibrating portion in the plan view and joining the holding portion of the vibrator layer and the second lid layer; and
a covering member covering an entire periphery of at least one of an inner surface and an outer surface of at least one of the first joining member and the second joining member,
wherein
the at least one of the first joining member and the second joining member is made of a first insulating material, and
the covering member is made of a second insulating material having a gas permeability lower than that of the first insulating material.

2. The piezoelectric vibrator according to claim 1, wherein
the second lid layer has an electrode on a side thereof opposite to a side facing the vibrator layer,
the first joining member is made of a metallic material, and
the second joining member is made of the first insulating material.

3. The piezoelectric vibrator according to claim 2, wherein the vibrator layer further has a functional element.

4. The piezoelectric vibrator according to claim 1, wherein the covering member does not extend onto surfaces of each of the first electrode layer and the second electrode layer of the vibrating portion.

5. The piezoelectric vibrator according to claim 1, wherein the covering member is on surfaces of each of the first electrode layer and the second electrode layer of the vibrating portion.

6. The piezoelectric vibrator according to claim 1, wherein the covering member does not extend onto a surface of the vibrator layer joined to the first joining member.

7. The piezoelectric vibrator according to claim 1, wherein the piezoelectric layer of the vibrator layer comprises a quartz crystal.

8. The piezoelectric vibrator according to claim 1, wherein the first lid layer and the second lid layer comprise a quartz crystal.

9. The piezoelectric vibrator according to claim 1, wherein at least one of the first lid layer and the second lid layer comprises silicon, ceramic, or glass.

10. The piezoelectric vibrator according to claim 1, wherein the covering member has a thickness of 1 nm to 100 nm.

11. The piezoelectric vibrator according to claim 1, wherein
the first insulating material comprises resin or glass, and
the second insulating material comprises aluminum oxide.

12. The piezoelectric vibrator according to claim 1, wherein
the covering member covers the entire periphery of the inner surface of the second joining member, and
the second joining member is made of the first insulating material.

13. The piezoelectric vibrator according to claim 12, wherein the covering member is on the surface of the crystal vibrating element, and a surface of the second lid layer facing the vibrating portion.

14. The piezoelectric vibrator according to claim 13, further comprising an electrode on a side of the second lid layer opposite to a side thereof facing the vibrator layer.

15. The piezoelectric vibrator according to claim 13, wherein the covering member is on surfaces of each of the first electrode layer and the second electrode layer of the vibrating portion.

16. The piezoelectric vibrator according to claim 1, wherein the covering member covers an entire periphery of the outer surfaces of both of the first joining member and the second joining member.

17. The piezoelectric vibrator according to claim 16, wherein the covering member does not extend onto surfaces of each of the first electrode layer and the second electrode layer of the vibrating portion.
